(19) United States
(12) Patent Application Publication
(10) Pub. No.: US 2023/0275051 A1
(43) Pub. Date: Aug. 31, 2023

(54) SEMICONDUCTOR DEVICE

(71) Applicant: RENESAS ELECTRONICS CORPORATION, Tokyo (JP)

(72) Inventor: Teruhiro KUWAJIMA, Tokyo (JP)

(21) Appl. No.: 17/993,350

(22) Filed: Nov. 23, 2022

(30) Foreign Application Priority Data
Feb. 25, 2022 (JP) 2022-028040

(51) Int. Cl. H01L 23/00

(52) U.S. Cl. CPC H01L 24/05; H01L 2224/04042; H01L 2224/05083; H01L 2224/05573; H01L 2224/02141; H01L 2224/02126; H01L 2224/05124; H01L 2224/05155; H01L 2224/05164; H01L 2224/05644

(57) ABSTRACT

A semiconductor device capable of suppressing formation of nodules on an upper surface of an electroless plating film will be provided. The semiconductor device includes a wiring, a cap film, a passivation film, a shielding film, and the electroless plating film. The wiring has a bonding pad. The passivation film is disposed so as to cover the wiring and the cap film. An opening penetrates through the passivation film and the cap film, and partially expose an upper surface of the bonding pad. The upper surface of the bonding pad exposed from the opening is divided into a first region and a second region. The shielding film is disposed on the second region. The electroless plating film is disposed on the first region and the shielding film.

### CROSS-REFERENCE TO RELATED APPLICATIONS

The disclosure of Japanese Patent Application No. 2022-028040 filed on Feb. 25, 2022, including the specification, drawings and abstract is incorporated herein by reference in its entirety.

### BACKGROUND

The present disclosure relates to a semiconductor device.

For example, Japanese Patent Laid-Open No. JP-A-2012-146720 (Patent Document 1) describes a semiconductor device. The semiconductor device according to the Patent Document 1 includes a wiring, a cap film, a passivation film, and an electroless plating film.

The wiring is made of aluminium. The wiring includes a bonding pad. The cap film is disposed on an upper surface of the wiring. The passivation film is disposed such that the passivation film covers the wiring. The cap film and the passivation film have an opening that partially expose an upper surface of the bonding pad. The electroless plating film is disposed on the upper surface of the bonding pad exposed from the opening of the cap film and the passivation film. A bonding wire is bonded to the electroless plating film.

### SUMMARY

Hillocks may be formed on an upper surface of a bonding pad. When an electroless plating film is formed on the upper surface of the bonding pad where the hillocks are existed, nodules (protrusions) may be formed on an upper surface of the electroless plating film above the hillocks. When the nodules are formed on the upper surface of the electroless plating film, a bonding strength with the bonding pad will be reduced.

Other objects and novel features will become apparent from the description of this specification and the accompanying drawings.

A semiconductor device of the present disclosures includes a wiring, a cap film, a passivation film, a shielding film, and the electroless plating film. The wiring has the bonding pad and is formed of aluminum or aluminum alloy. The cap film is disposed on an upper surface of the wiring. The passivation film is disposed such that the passivation film covers the wiring and the cap film. in the cap film and the passivation film, an opening is formed such that the opening penetrates through the cap film and the passivation film, and exposes a part of an upper surface of the bonding pad. The upper surface of the bonding pad exposed from the opening is divided into a first region and a second region. The shielding film is disposed on the first region. The electroless plating film is disposed on the second region and the shielding film.

According to the semiconductor devices of the present disclosure, the nodules can be suppressed from being formed on the upper surface of the electroless plating film.

### BRIEF DESCRIPTION OF THE DRAWINGS

FIG. 1 is a cross-sectional view of a semiconductor device DEV1.

FIG. 2 is a cross-sectional view of the semiconductor device DEV1 in a vicinity of a bonding pad BP.

FIG. 3 is a flow chart showing a manufacturing method of the semiconductor device DEV1

FIG. 4 is a cross-sectional view for illustrating a step of forming a wiring S1.

FIG. 5 is a cross-sectional view for illustrating a step of forming a first passivation film S2.

FIG. 6 is a cross-sectional view for illustrating a step of first etching S3.

FIG. 7 is a cross-sectional view for illustrating a step of forming a second passivation film S4.

FIG. 8 is a cross-sectional view for illustrating a step of second etching S5.

FIG. 9 is a cross-sectional view of a semiconductor device DEV2 in a vicinity of a bonding pad BP.

FIG. 10 is a cross-sectional view of the semiconductor device DEV1 according to a modified example of the first embodiment in the vicinity of the bonding pad BP.

FIG. 11A is a first exemplary layout of a shielding film SF.

FIG. 11B is a second exemplary layout of the shielding film SF.

FIG. 11C is a third exemplary layout of the shielding film SF.

FIG. 12 is a cross-sectional view of a semiconductor device DEV3 in a vicinity of a bonding pad BP.

FIG. 13 is a flow chart showing a manufacturing method of the semiconductor device DEV3.

FIG. 14 is a cross-sectional view for illustrating a step of third etching S7.

FIG. 15 is a cross-sectional view of a semiconductor device DEV3 according to a first modified example of the second embodiment in the vicinity of the bonding pad BP.

FIG. 16 is a cross-sectional view of a semiconductor device DEV3 according to a second modified example of the second embodiment in the vicinity of the bonding pad BP.

FIG. 17 is a cross-sectional view of a semiconductor device DEV4 in a vicinity of a bonding pad BP.

FIG. 18 is a flow chart showing a manufacturing method of the semiconductor device DEV4.

FIG. 19 is a cross-sectional view for illustrating a step of fourth etching S8.

FIG. 20 is a cross-sectional view for illustrating a step of fifth etching S9.

FIG. 21 is a cross-sectional view of a semiconductor device DEV4 according to a modified example of a third embodiment in the vicinity of the bonding pad BP.

FIG. 22 is a cross-sectional view of a semiconductor device DEV5 in a vicinity of a bonding pad BP.

### DETAILED DESCRIPTION

Details of embodiments of the present disclosure will be described with reference to the drawings. In the following drawings, the same or corresponding parts are denoted by the same reference numerals, and redundant description will not be repeated.

### First Embodiment

A semiconductor device according to a first embodiment will be described. The semiconductor device according to the first embodiment is a semiconductor device DEV1.

### Structure of the Semiconductor Device DEV1

A schematic configuration of the semiconductor device DEV1 will be described below.

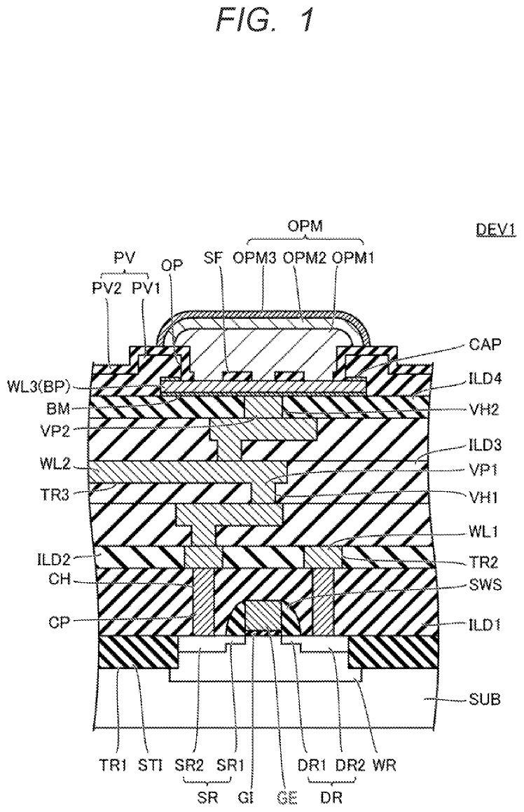

FIG. 1 is a cross-sectional view of the semiconductor device DEV1. As shown in FIG. 1, the semiconductor device DEV1 includes a semiconductor substrate SUB, a gate dielectric film GI, a gate electrode GE, sidewall spacers SWS, and an element isolation film STI. The semiconductor device DEV1 further includes an interlayer insulating film ILD1, a contact plug CP, an interlayer insulating film ILD2, a wiring WL1, a plurality of interlayer insulating films ILD3, a plurality of wiring WL2, a via plug VP1, an interlayer insulating film ILD4, a via plug V2, wiring WL3, a barrier metal BM, a cap film CAP, a passivation film PV, and an electroless plating film OPM.

The semiconductor substrate SUB is made of, for example, monocrystalline silicon (Si). The semiconductor substrate SUB has a source region SR, a drain region DR, and a well region WR.

The source region SR and the drain region DR are disposed in an upper surface of the semiconductor substrate SUB. The source region SR and the drain region DR are spaced apart from each other. A conductivity type of the source region SR and the drain region DR are a first conductivity type. The first conductivity type is, for example, n-type.

The source region SR has a first portion SR1 and a second portion SR2. The drain region DR includes a first portion DR1 and a second portion DR2. The first portion SR1 is closer to the drain region DR than the second portion SR2. The first portion DR1 is closer to the source region SR than the second portion DR2. A dopant concentration in the first portion SR1 is lower than a dopant concentration in the second portion SR2. A dopant concentration in the first portion DR1 is lower than a dopant concentration in the second portion DR2. That is, the source region SR and the drain region DR are LDD (Lightly Doped Diffusion) structure.

The well region WR is disposed in the upper surface of the semiconductor substrate SUB such that the well region WR surrounds the source region SR and the drain region DR. A conductivity type of the well region WR is a second conductivity type. The second conductivity type is opposite conductivity type of the first conductivity type. When the first conductivity type is, for example, n-type, the second conductivity type is p-type. A portion of the well region WR disposed in the upper surface of the semiconductor substrate SUB and between the source region SR and the drain region DR may be called a channel region.

The gate dielectric film GI is disposed on the upper surface of the semiconductor substrate SUB between the source region SR and the drain region DR. The gate dielectric film GI is made of, for example, silicon oxide (SiO2). That is, the gate dielectric film GI is disposed on the channel region. The gate electrode GE is disposed on the gate dielectric film GI. That is, the gate electrode GE is disposed to face the channel region while being insulated by the gate dielectric film GI. The gate electrode GE is formed of polycrystalline silicon containing dopants. The source region SR, the drain region DR, the well region WR, the gate dielectric film GI, and the gate electrode GE constitute a transistor.

The sidewall spacers SWS is disposed on the first portion SR1 and the first portion DR1 such that the sidewall spacers SWS contact with side surfaces of the gate electrode GE.

A trench TR1 is formed in the upper surface of the semiconductor substrate SUB. In the trench TR1, the upper surface of the semiconductor substrate SUB is recessed toward a bottom surface of the semiconductor substrate SUB. The trench TR1 surrounds the well region WR in plan view (when viewed from the upper surface side of the semiconductor substrate SUB along a normal direction of the upper surface of the semiconductor substrate SUB). An inside the trench TR1, the element isolation film STI is embedded. The element isolation film STI is made of, for example, silicon oxide. Thus, adjacent transistors are isolated from each other.

The interlayer insulating film ILD1 is disposed on the upper surface of the semiconductor substrate SUB such that the interlayer insulating film ILD1 covers the gate electrode GE, the sidewall spacers SWS, and the element isolation film STI. The interlayer insulating film ILD1 is formed of, for example, silicon oxide. A contact hole CH is formed in the interlayer insulating film ILD1. The contact hole CH penetrates the interlayer insulating film ILD1 along a thickness direction. The source region SR (the second portion SR2) and the drain region DR (the second portion DR2) are exposed from the contact hole CH. Although not shown, the gate electrode GE is exposed from the contact hole CH.

The contact plug CP is embedded in the contact hole CH. A lower end of the contact plug CP is electrically connected to the source region SR (the second portion SR2), the drain region DR (the second portion DR2) or the gate electrode GE. The contact plug CP is made of, for example, tungsten (W).

The interlayer insulating film ILD2 is disposed on the interlayer insulating film ILD1. The interlayer insulating film ILD2 is formed of, for example, silicon oxide. A trench TR2 is formed in the interlayer insulating film ILD2. The trench TR2 penetrates through the interlayer insulating film ILD2 along the thickness direction. Inside the trench TR2, the wiring WL1 is embedded. The wiring WL1 is electrically connected to an upper end of the contact plug CP. The wiring WL1 is made of, for example, copper (Cu) or copper alloy.

The plurality of interlayer insulating films ILD3 are stacked and disposed on the interlayer insulating film ILD2. The plurality of interlayer insulating films ILD3 is formed of silicon oxide. A trench TR3 and a via hole VH1 are formed in the interlayer insulating film ILD3. The trench TR3 is formed on the upper surface of the interlayer insulating film ILD3. In the trench TR3, the upper surface of the interlayer insulating film ILD3 is recessed toward a bottom surface of the interlayer insulating film ILD3. The via hole VH1 penetrates through the interlayer insulating film ILD3 along the thickness direction. An upper end of the via hole VH1 is open at a bottom surface of the trench TR3, and a lower end of the via hole VH1 is open at the bottom surface of the interlayer insulating film ILD3.

The wiring WL2 and the via plug VP1 are embedded in the trench TR3 and the via hole VH1, respectively. The wiring WL2 and the via plug VP1 are formed integrally. The wiring WL2 and the via plug VP1 are made of, for example, copper or copper alloy. The via plug VP1 electrically connects with the wiring WL2 and the wiring WL1 underlying the wiring WL2.

The interlayer insulating film ILD4 is disposed on the uppermost layer of the plurality of interlayer insulating films ILD3. The interlayer insulating film ILD4 is formed of, for example, silicon oxide. A via hole VH2 is formed in the interlayer insulating film ILD4. The via hole VH2 penetrates through the interlayer insulating film ILD4 along the thickness direction. The via plug VP2 is embedded in the via hole VH2. The via plug VP2 is formed of, for example, copper or copper alloy. A lower end of the via plug VP2 is electrically connected to the wiring WL2.

A wiring WL3 is disposed on the interlayer insulating film ILD4. The Wiring WL3 is made of aluminium (Al). The wiring WL3 may be made of aluminium alloy. The wiring WL3 is electrically connected to an upper end of the via plug VP2. The wiring WL3 has a bonding pad BP. The barrier metal BM is disposed between the wiring WL3 and the interlayer insulating film ILD4. The cap film CAP is disposed on an upper surface of the wiring WL3. The barrier metal BM and the cap film CAP are made of, for example, titanium nitride (TiN).

The passivation film PV is disposed on the interlayer insulating film ILD4 such that the passivation film PV covers the wiring WL3 and the cap film CAP. An opening OP is formed in the passivation film PV and the cap film CAP. The opening OP penetrates through the passivation film PV and the cap film CAP along the thickness direction. The upper surface of the wiring WL3 is exposed from the opening OP. The electroless plating film OPM is disposed on the upper surface of the wiring WL3 exposed from the opening OP. The electroless plating film OPM is also disposed on the passivation film PV around the opening OP. The electroless plating film OPM is a film formed by electroless plating. Although not shown in FIG. 1, a bonding wire BW is bonded to an upper surface of the electroless plating film OPM.

### Detailed Configuration of the Semiconductor Device DEV1

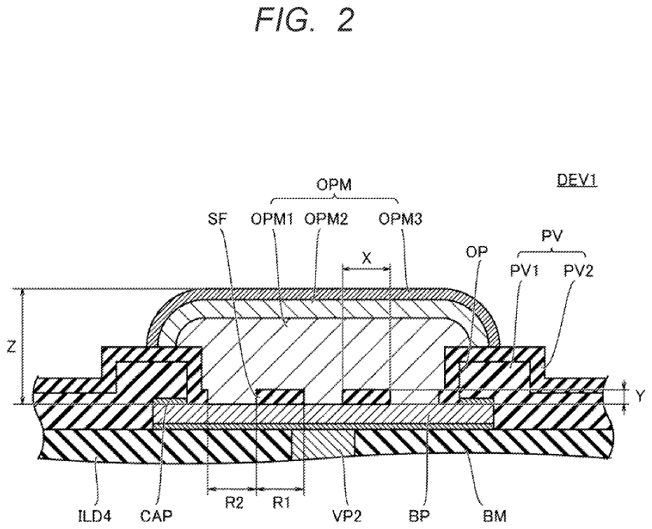

FIG. 2 is a cross-sectional view of the semiconductor device DEV1 vicinity the bonding pad BP. As shown in FIG. 2, the passivation film PV includes a first passivation film PV1 and a second passivation film PV2. The first passivation film PV1 is disposed on the interlayer insulating film ILD4 such that the first passivation film PV1 covers the wiring WL3 and the cap film CAP. the second passivation film PV2 is disposed on the first passivation film PV1. The second passivation film PV2 is also disposed on an inner wall surface of the opening OP.

The second passivation film PV2 is formed of a material other than materials of the first passivation film PV1. The first passivation film PV1 is formed of, for example, silicon oxide, and the second passivation film PV2 is formed of, for example, silicon nitride (SiN).

The upper surface of the wiring WL3 exposed from the opening OP has a first region R1 and a second region R2. A shielding film SF is disposed on the first region R1. The shielding film SF is formed of same material as a material of the second passivation film PV2. The shielding film SF is not disposed on the second region R2. From another viewpoint, the upper surface of the wiring WL3 is exposed between the shielding films SF.

The electroless plating film OPM includes, for example, a nickel layer OPM1, a palladium layer OPM2, and a gold layer OPM3. The nickel layer OPM1 is a layer of nickel (Ni) formed by electroless plating. The palladium layer OPM2 is a layer of palladium (Pd) formed by electroless plating. The gold layer OPM3 is a layer of gold (Au) formed by electroless plating. The nickel layer OPM1 is disposed on the shielding film SF and the second region R2. The palladium layer OPM2 is disposed on the nickel layer OPM1. The gold layer OPM3 is disposed on the palladium layer OPM2. However, a layer configuration of the electroless plating film OPM is not limited to this.

A width of the shielding film SF is defined as X. A thickness of the shielding film SF is defined as Y. A thickness of the electroless plating film OPM is defined as Z. X, Y and Z preferably satisfy a relationship of Y<Z and X≤(Z−Y)×0.5. First, the electroless plating film OPM is grown on the second region R2. When the electroless plating film OPM grows to some extent, the electroless plating film OPM also grows on the shielding film SF. Consequently, when the above-described relationship is satisfied, the electroless plating film OPM grown from a plurality of second regions R2 contacts and is integrated on the shielding film SF.

### Manufacturing Method of the Semiconductor Device DEV1

Manufacturing method of the semiconductor device DEV1 is described below.

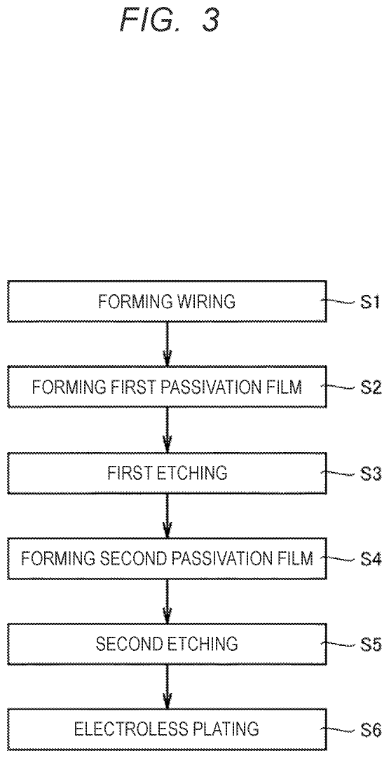

FIG. 3 is a flow chart showing a manufacturing method of the semiconductor device DEV1. As shown in FIG. 3, the manufacturing method of the semiconductor device DEV1 includes a step of forming the wiring S1, a step of forming the first passivation film S2, a step of first etching S3, a step of forming the second passivation film S4, a step of second etching S5, and a step of electroless plating S6.

Although not shown, prior to the step of forming the wiring S1, steps of forming structure of the semiconductor device DEV1 underlying the wiring WL3 are performed. These steps may be performed by a conventionally known method, and thus description thereof is omitted here.

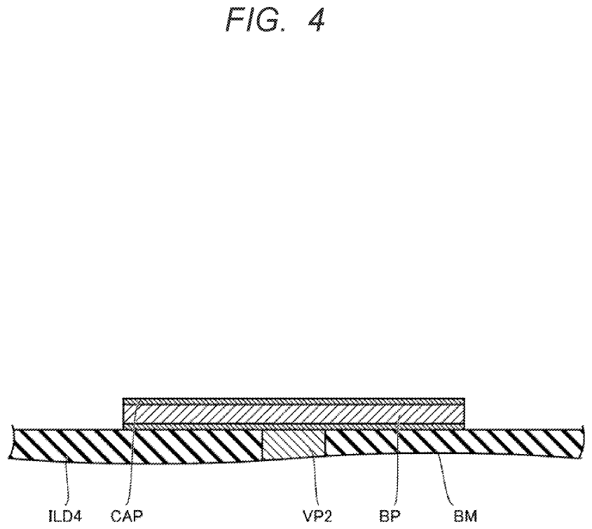

FIG. 4 is a cross-sectional view for illustrating the step of forming the wiring S1. As shown in FIG. 4, in the step of forming the wiring S1, the barrier metal BM, the wiring WL3, and the cap film CAP are formed. In the step of forming the wiring S1, first, constituent materials of the barrier metal BM, the wiring WL3, and the cap film CAP are sequentially formed on the interlayer insulating film ILD4. The constituent materials of the barrier metal BM, the wiring WL3, and the cap film CAP are formed, for example, by sputtering. Second, the deposited constituent materials of the barrier metal BM, the wiring WL3, and the cap film CAP are patterned. This patterning is performed by etching using a photoresist patterned by photolithography as a mask.

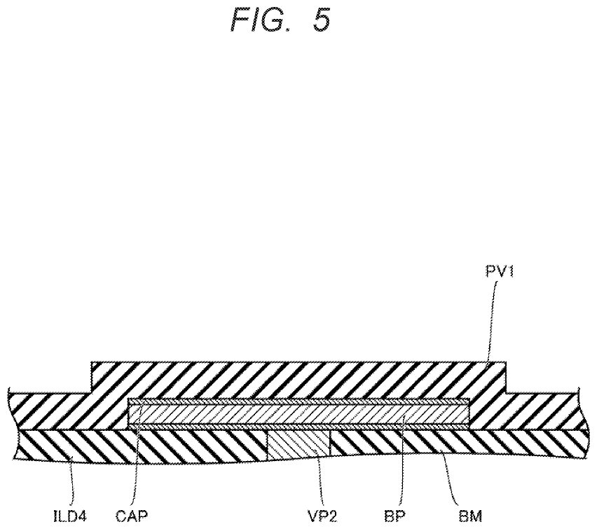

FIG. 5 is a cross-sectional view for illustrating the step of forming the first passivation film S2. As shown in FIG. 5, in the step of forming the first passivation film S2, the first passivation film PV1 is formed so as to cover the cap film CAP and the wiring WL3. The first passivation film PV1 is formed by, for example, CVD (Chemical Vapor Deposition).

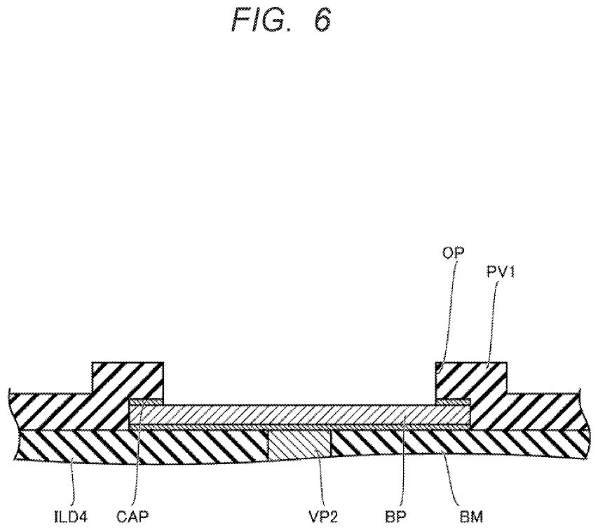

FIG. 6 is a cross-sectional view for illustrating the step of first etching S3. As shown in FIG. 6, in the step of first etching S3, the opening OP is formed in the first passivation film PV1 and the cap film CAP. The opening OP is formed by etching using a photoresist patterned by photolithography as a mask.

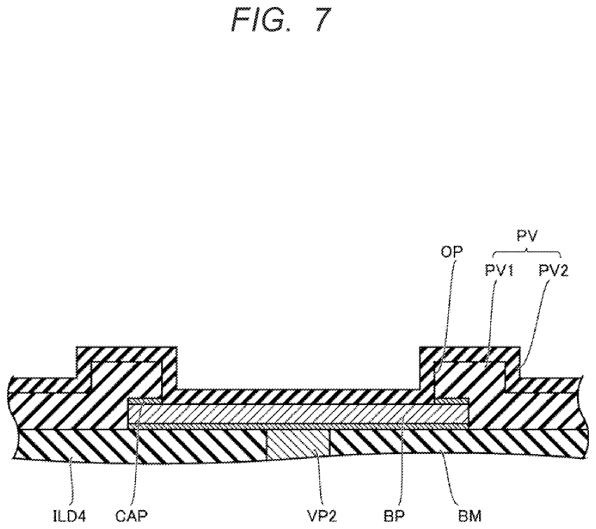

FIG. 7 is a cross-sectional view for illustrating a step of forming the second passivation film S4. As shown in FIG. 7, in the step of forming the second passivation film S4, the second passivation film PV2 is formed on the first passivation film PV1. At this time, the first passivation film PV1 is also formed on an inner wall surface of the opening OP and an upper surface of the bonding pad BP exposed from the opening OP. The second passivation film PV2 is formed by, for example, CVD.

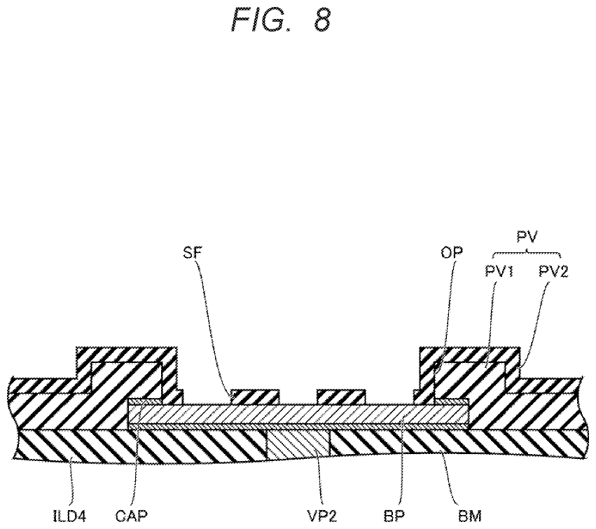

FIG. 8 is a cross-sectional view for illustrating the step of second etching S5. As shown in FIG. 8, in the step of second etching S5, the second passivation film PV2 disposed on the upper surface of the wiring WL3 exposed from the opening OP is patterned. This patterning is performed by etching using a photoresist patterned by photolithography as a mask. The second passivation film PV2 disposed on the upper surface of the wiring WL3 exposed from the opening OP is patterned to form the shielding film SF.

In the step of electroless plating S6, the electroless plating of nickel, the electroless plating of palladium, and the electroless plating of gold are sequentially performed, thereby the electroless plating film OPM is formed on the shielding film SF, on the second region R2 and on the passivation film PV around the opening OP. As described above, a structure of the semiconductor device DEV1 shown in FIGS. 1 and 2 is formed.

### Effect of the Semiconductor Device DEV1

In the following, an effect of the semiconductor device DEV1 will be described in comparison with a comparative example. A semiconductor device according to the comparative example is defined as a semiconductor device DEV2.

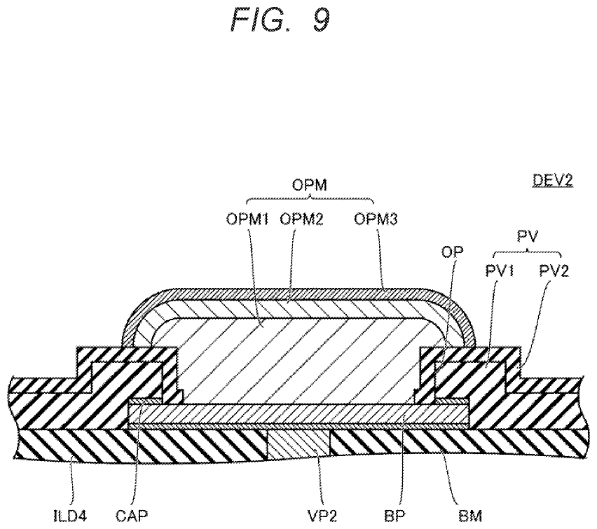

FIG. 9 is a cross-sectional view of the semiconductor device DEV2 in a vicinity of a bonding pad BP. As shown in FIG. 9, in the semiconductor device DEV2, a shielding film SF is not disposed on an upper surface of the bonding pad BP exposed from an opening OP. Otherwise, a configuration of the semiconductor device DEV2 is the same as that of the semiconductor device DEV1.

Since a wiring WL3 is made of aluminum or aluminum alloy, the hillocks may be formed on the upper surface of the bonding pad BP by applying heat while the upper surface of the bonding pad BP is exposed. When an electroless plating film OPM is formed on the upper surface of the bonding pad BP with the hillocks formed thereon, nodules are formed on an upper surface of an electroless plating film OPM. Such the nodules reduce a bonding strength between the bonding pad BP and the bonding wire BW. In the semiconductor device DEV2, since an area of the upper surface of the bonding pad BP exposed from the opening OP is large, the hillocks are likely to occur, and consequently, the bonding strength with the bonding wire BW is likely to decrease.

On the other hand, in the semiconductor device DEV1, the upper surface of the bonding pad BP exposed from the opening OP is divided into the first region R1 and the second region R2, and the shielding film SF is disposed on the first region R1. Therefore, in the semiconductor device DEV1, the hillocks are unlikely to occur in the first region R1, and the nodules are unlikely to be formed on the upper surface of the electroless plating film OPM. As described above, in the semiconductor device DEV1, the nodules in the upper surface of the electroless plating film OPM is suppressed, so that the bonding strength with the bonding wire BW can be secured.

### Modified Example of the First Embodiment

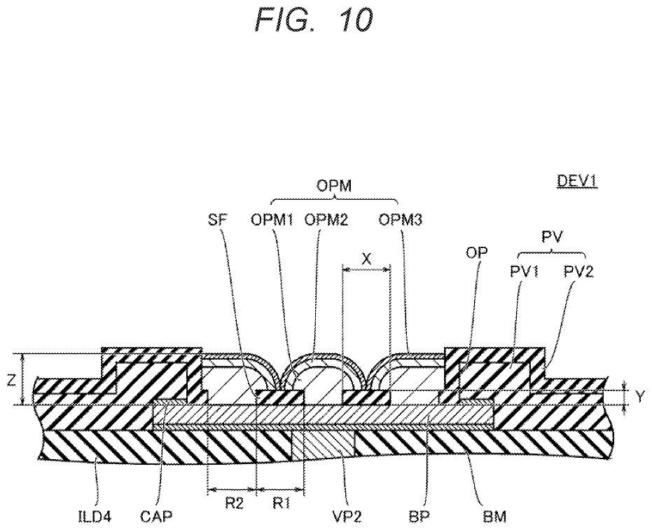

FIG. 10 is a cross-sectional view of a semiconductor device DEV1 according to a modified example of the first embodiment in the vicinity of the bonding pad BP. As shown in FIG. 10, in the semiconductor device DEV1, a relationship of Y<Z and X>(Z−Y)×0.5 may be satisfied. That is, in the semiconductor device DEV1, the 20 electroless plating film OPM grown from each of the second regions R2 may not be integrated. Note that, when a relationship of Y<Z and X≤(Z−Y)×0.5 is satisfied (i.e., when the electroless plating film OPM grown from each of the second regions R2 are integrated), a bonding area with the bonding wire BW is increased, so that the bonding strength with the bonding wire BW is improved.

### Example of Layout of the Shielding Film

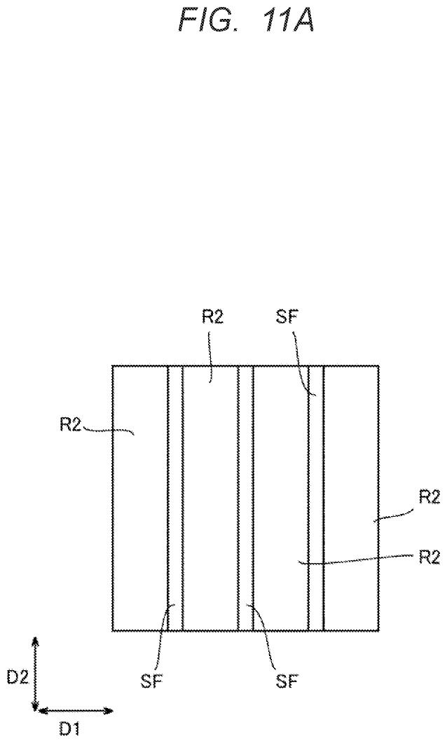

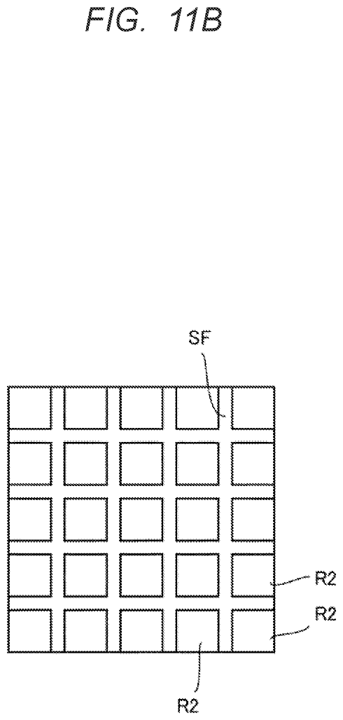

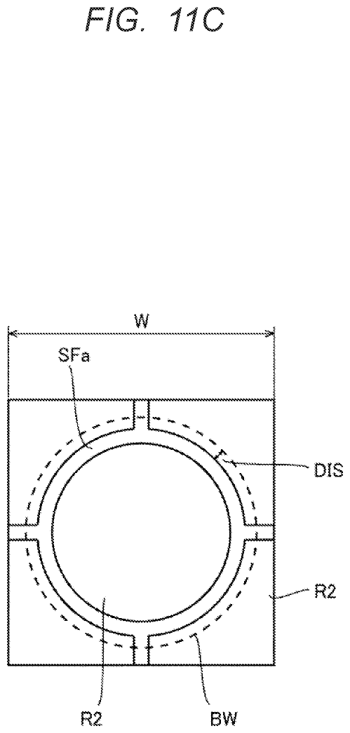

FIG. 11A is a first exemplary layout of the shielding film SF. As shown in 11A, the shielding film SF may be divided into a plurality of portions. The plurality of portions of the shielding film SF is disposed side by side at intervals along a first direction D1. Each of the plurality of portions of the shielding film SF extends along a second direction D2 in plan view. The second direction D2 is a direction perpendicular to the first direction D1. From another viewpoint, the second region R2 is divided into a plurality of band-shaped regions, and the plurality of band-shaped regions are disposed side by side at intervals along the first direction D1.

FIG. 11B is a second exemplary layout of the shielding film SF. As shown in 11B, the second region R2 may be divided into a plurality of regions. Each of the plurality of second regions R2 may be disposed in a grid pattern in plan view.

FIG. 11C is a third exemplary layout of the shielding film SF. Note that, in the drawing 11C, a position of a peripheral portion of the bonding wire BW bonded to the electroless plating film OPM is indicated by a dotted line. As shown in 11C, the shielding film SF may have a portion which is an annular shape in plan view (an annular portion SFa). The annular portion SFa is disposed inside the position of the peripheral portion of the bonding wire BW bonded to the electroless plating film OPM in plan view.

A width of the bonding pad BP in plan view is defined as a width W. When there is a longitudinal direction in the bonding pad BP in plan view, the width W is measured in the longitudinal direction. A distance between the annular portion SFa and the position of the peripheral portion of the bonding wire BW bonded to the electroless plating film OPM is defined as a distance DIS. The distance DIS divided by the width W is preferably 0.2 or less.

When the nodules on the upper surface of the electroless plating film OPM is in the vicinity of a peripheral edge of the bonding wire BW bonded to the electroless plating film OPM, peeling of the bonding wire BW is particularly likely to occur. The nodules are less likely to be formed on the upper surface of the electroless plating film OPM above the annular portion SFa. Therefore, when the distance DIS divided by the width W is 0.2 or less, peeling of the bonding wire BW can be further suppressed.

### Second Embodiment

A semiconductor device according to a second embodiment will be described. The semiconductor device according to the second embodiment is defined as a semiconductor device DEV3. Here, differences from the semiconductor device DEV1 will be mainly described, and redundant description will not be repeated.

### Configuration of the Semiconductor Device DEV3

A configuration of the semiconductor device DEV3 will be described below.

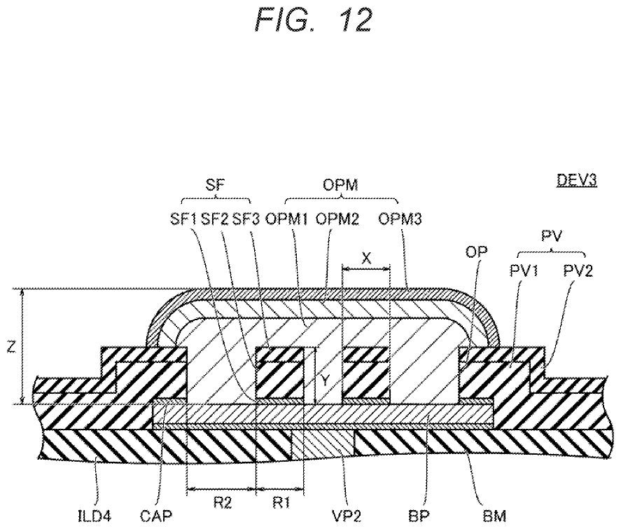

FIG. 12 is a cross-sectional view of the semiconductor device DEV3 in a vicinity of a bonding pad BP. As shown in FIG. 12, in the semiconductor device DEV3, a shielding film SF includes a first layer SF1, a second layer SF2, and a third layer SF3. The first layer SF1 is disposed on the first region R1. The first layer SF1 is formed of same material as a material of a cap film CAP. The second layer SF2 is disposed on the first layer SF1. The second layer SF2 is formed of same material as a material of a first passivation film PV1. The third layer SF3 is disposed on the second layer SF2. The third layer SF3 is formed of same material as a material of a second passivation film PV2.

Otherwise, the configuration of the semiconductor device DEV3 is the same as that of the semiconductor device DEV1. In the semiconductor device DEV3, a relationship of Y<Z and X≤(Z−Y)×0.5 is satisfied, and an electroless plating film OPM grown from each of second regions R2 is integrated.

### Manufacturing Method of the Semiconductor Device DEV3

A manufacturing method of the semiconductor device DEV3 is described below.

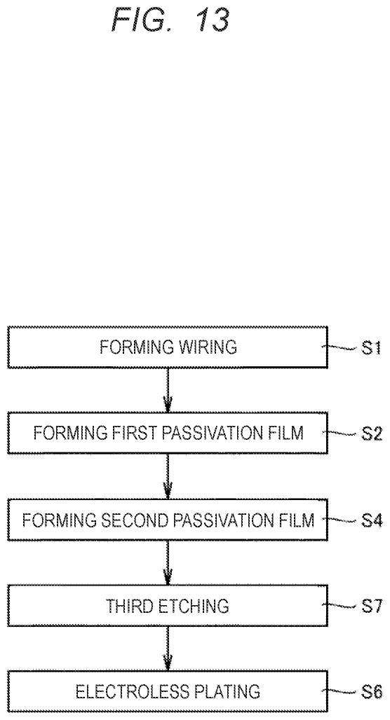

FIG. 13 is a flow chart showing a manufacturing method of the semiconductor device DEV3. As shown in FIG. 13, the manufacturing method of the semiconductor device DEV3 includes a step of forming a wiring S1, a step of forming the first passivation film S2, a step of forming a second passivation film S4, and a step of electroless plating S6. The manufacturing method of the semiconductor device DEV3 has a step of third etching S7 instead of a step of first etching S3 and a step of second etching S5. In the manufacturing method of the semiconductor device DEV3, the step of forming the second passivation film S4 is performed after the step of forming the first passivation film S2, the step of third etching S7 is performed after the step of forming the second passivation film S4, and the step of electroless plating S6 is performed after the step of third etching S7.

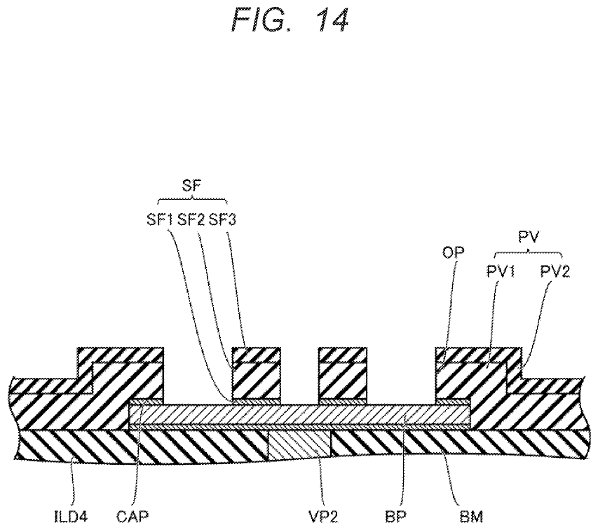

FIG. 14 is a cross-sectional view for illustrating the step of third etching S7. In the step of third etching S7, as shown in FIG. 14, patterning of the first passivation film PV1, the second passivation film PV2, and the cap film CAP is collectively performed. This patterning is performed by etching using a photoresist patterned by photolithography as a mask. As a result, an opening OP and the shielding film SF are collectively formed. Otherwise, the manufacturing method of the semiconductor device DEV3 is the same as the manufacturing method of the semiconductor device DEV1.

### Effect of the Semiconductor Device DEV3

In the following, an effect of the semiconductor device DEV3 will be described.

In the manufacturing method of the semiconductor device DEV1, two etching steps (the step of first etching S3 and the step of second etching S5) are required in order to form the opening OP and the shielding film SF. On the other hand, in the manufacturing method of the semiconductor device DEV3, a single etching step (the step of third etching S7) may be performed to form the opening OP and the shielding film SF. As described above, according to the semiconductor device DEV3, it is possible to simplify a manufacturing method.

### First Modified Example of the Second Embodiment

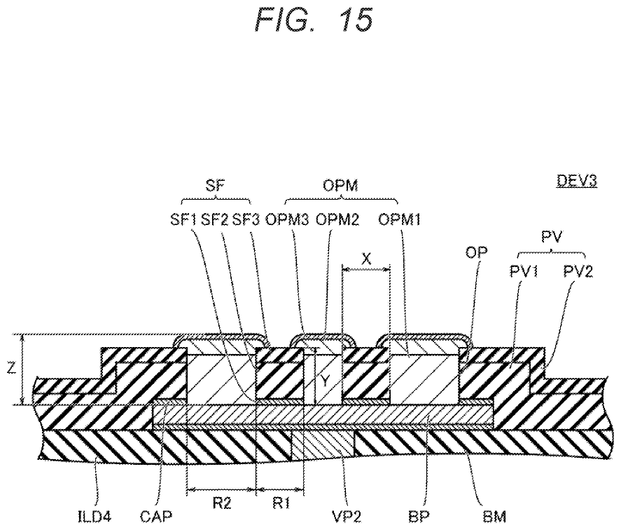

FIG. 15 is a cross-sectional view of a semiconductor device DEV3 according to a first modified example of the second embodiment in the vicinity of the bonding pad BP. As shown in FIG. 15, in the semiconductor device DEV3, a relationship of Y<Z and X>(Z−Y)×0.5 may be satisfied. That is, in the semiconductor device DEV3, the electroless plating film OPM grown from each of the second regions R2 may not be integrated.

### Second Modified Example of the Second Embodiment

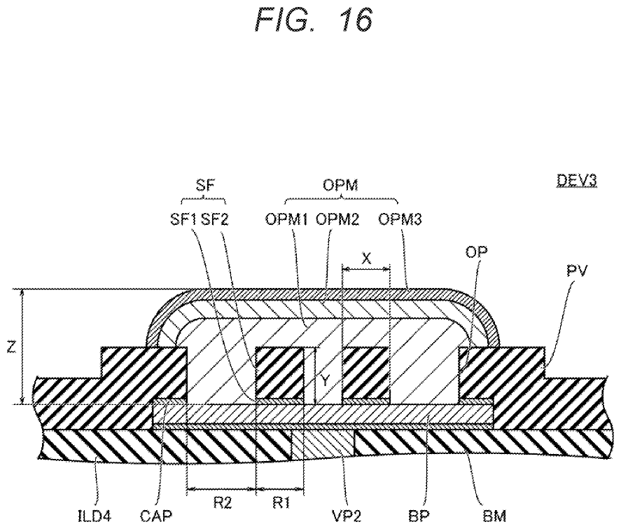

FIG. 16 is a cross-sectional view of a semiconductor device DEV3 according to a second modified example of the second embodiment in the vicinity of the bonding pad BP. As shown in FIG. 16, in the semiconductor device DEV3, the passivation film PV may not have the first passivation film PV1 and the second passivation film PV2. That is, in the semiconductor device DEV3, the passivation film PV may be one layer structure instead of the dual passivation structure. As a result, in the semiconductor device DEV3, the shielding film SF may be formed of the first layer SF1 and the second layer SF2, and the second layer SF2 may be formed of same material as a material of the passivation film PV.

### Third Embodiment

A semiconductor device according to a third embodiment will be described. The semiconductor device according to the third embodiment is defined as a semiconductor device DEV4. Here, differences from the semiconductor device DEV1 will be described, and duplicate descriptions will not be repeated.

### Configuration of the Semiconductor Device DEV4

A configuration of the semiconductor device DEV4 will be described below.

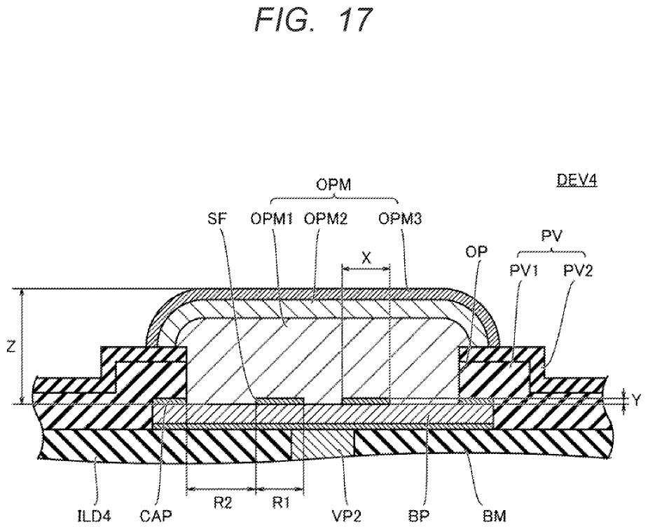

FIG. 17 is a cross-sectional view of the semiconductor device DEV4 in a vicinity of a bonding pad BP. As shown in FIG. 17, in the semiconductor device DEV4, a shielding film SF is formed of same material as a material of a cap film CAP.

Otherwise, the configuration of the semiconductor device DEV4 is the same as that of the semiconductor device DEV1. Note that, in the semiconductor device DEV4, a relationship of Y<Z and X≤(Z−Y)×0.5 is satisfied, and an electroless plating film OPM grown from each of second regions R2 is integrated.

### Manufacturing Method of the Semiconductor Device DEV4

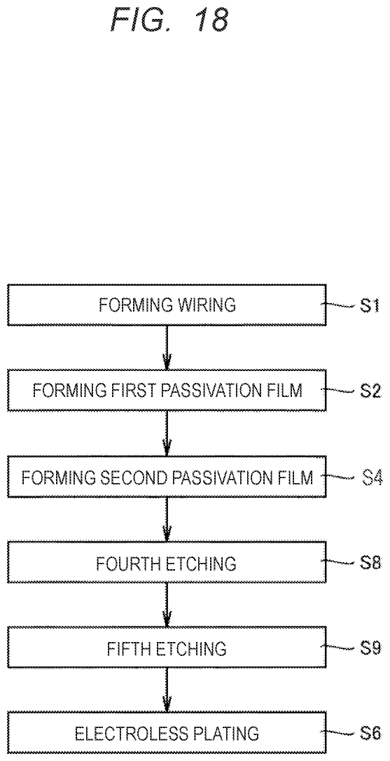

FIG. 18 is a flow chart showing a manufacturing method of the semiconductor device DEV4. As shown in FIG. 18, the manufacturing method of the semiconductor device DEV4 includes a step of forming a wiring S1, a step of forming a first passivation film S2, a step of forming a second passivation film S4, and a step of electroless plating S6. The manufacturing method of the semiconductor device DEV4 includes a step of fourth etching S8 and a step of fifth etching S9 instead of a step of first etching S3 and a step of second etching S5.

In the manufacturing method of the semiconductor device DEV4, the step of forming the second passivation film S4 is performed after the step of forming first passivation film S2, and the step of fourth etching S8 is performed after the step of forming the second passivation film S4. In the manufacturing method of the semiconductor device DEV4, the step of fifth etching S9 is performed after the step of fourth etching S8, and the step of electroless plating S6 is performed after the step of fifth etching S9.

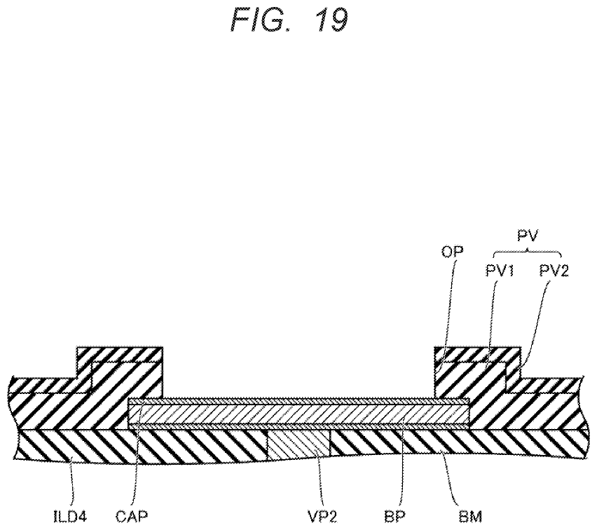

FIG. 19 is a cross-sectional view for illustrating the step of fourth etching S8. In the step of fourth etching S8, as shown in FIG. 19, patterning of a first passivation film PV1 and a second passivation film PV2 is collectively performed. This patterning is performed by etching using a photoresist patterned by photolithography as a mask.

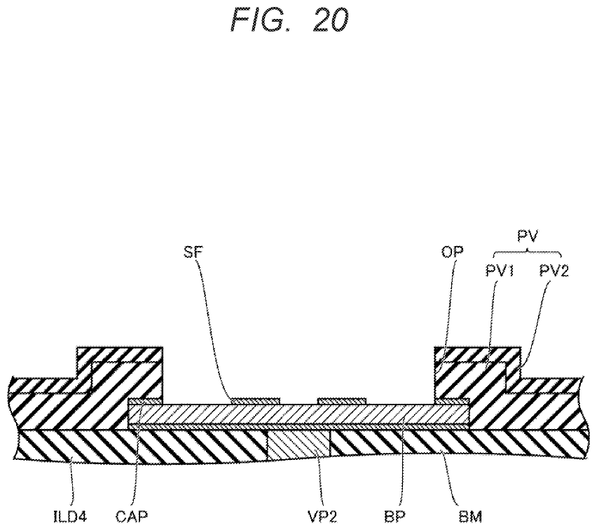

FIG. 20 is a cross-sectional view for illustrating the step of fifth etching S9. In the step of fifth etching S9, the cap film CAP is patterned to form the shielding film SF. This patterning is performed by etching using a photoresist patterned by photolithography as a mask. Otherwise, the manufacturing method of the semiconductor device DEV4 is the same as the manufacturing method of the semiconductor device DEV1.

In the semiconductor device DEV4, since the shielding film SF is formed by patterning the cap film CAP, a thickness (value of Y) of the shielding film SF can be made smaller than that of the semiconductor device DEV1 and the semiconductor device DEV3. Therefore, even when a thickness (value of Z) of the electroless plating film OPM is small, the relationship of Y<Z and X≤(Z−Y)×0.5 can be satisfied (i.e., it becomes possible to integrate the electroless plating film OPM grown from each of the second regions R2).

### Modified Example of the Third Embodiment

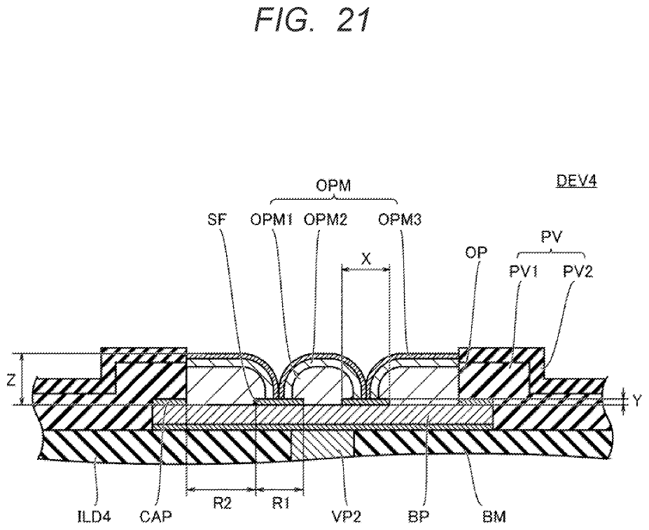

FIG. 21 is a cross-sectional view of a semiconductor device DEV4 according to a modified example of the third embodiment in the vicinity of the bonding pad BP. As shown in FIG. 21, in the semiconductor device DEV4, a relationship of Y<Z and X>(Z−Y)×0.5 may be satisfied. That is, in the semiconductor device DEV4, the electroless plating film OPM grown from each of the second regions R2 may not be integrated.

### Fourth Embodiment

A semiconductor device according to a fourth embodiment will be described. The semiconductor device according to the fourth embodiment is defined as a semiconductor device DEV5. Here, differences from the semiconductor device DEV3 will be described, and duplicate descriptions will not be repeated.

### Configuration of the Semiconductor Device DEV5

A configuration of the semiconductor device DEV5 will be described below.

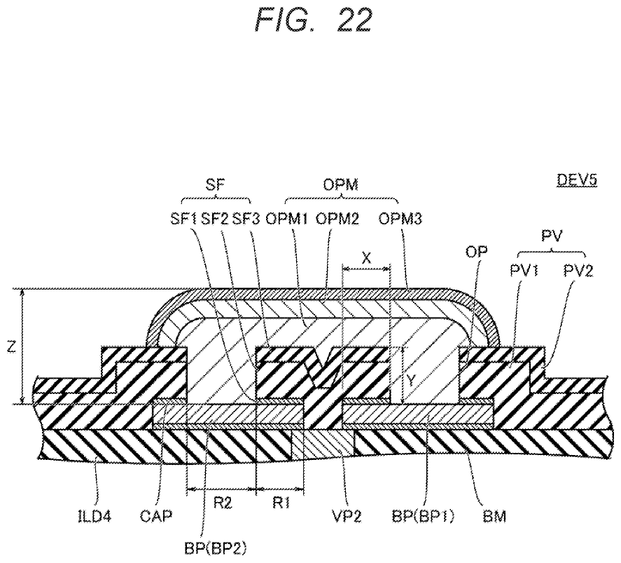

FIG. 22 is a cross-sectional view of the semiconductor device DEV5 in a vicinity of a bonding pad BP. As shown in FIG. 22, in the semiconductor device DEV5, the bonding pad BP is divided into a plurality of portions. In the embodiment shown in FIG. 22, the bonding pad BP is divided into a first portion BP1 and a second portion BP2. Otherwise, the configuration of the semiconductor device DEV4 is the same as that of the semiconductor device DEV1. Note that, in the semiconductor device DEV4, a relationship of Y<Z and X≤(Z−Y)×0.5 is satisfied, and an electroless plating film OPM grown from each of second regions R2 is integrated.

In the above description, as an example, the semiconductor device DEV5 is obtained by applying the configuration in which the bonding pad BP is divided into the plurality of portions to the semiconductor device DEV3. However, the configuration in which the bonding pad BP is divided into the plurality of portions may be applied to the semiconductor device DEV1 or the semiconductor device DEV4.

### Effect of the Semiconductor Device DEV5

As a surface area of the bonding pad BP increases, the hillocks are more likely to occur on an upper surface of the bonding pad BP exposed from an opening OP. In the semiconductor device DEV5, since the bonding pad BP is divided into the plurality of portions, the surface area of each portion of the bonding pad BP is smaller than that of the semiconductor device DEV3. Therefore, according to the semiconductor device DEV5, it is possible to further suppress an occurrence of the hillocks on the upper surface of the bonding pad BP and, in turn, the occurrence of the nodules on the upper surface of the electroless plating film OPM.

Although the invention made by the present inventor has been described in detail based on the embodiments, it is needless to say that the present invention is not limited to the above described embodiments and can be variously modified without departing from the gist thereof.

What is claimed is:

1. A semiconductor device comprising:
a wiring;
a cap film;
5 a passivation film;
a shielding film; and
an electroless plating film, wherein
the wiring has a bonding pad is formed of aluminum or aluminum alloy,
the cap film is disposed on an upper surface of the wiring,
the passivation film is disposed such that the passivation film covers the wiring and the cap film,
in the cap film and the passivation film, an opening is formed such that the opening penetrates through the cap film and the passivation film, and exposes a part of an upper surface of the bonding pad,
the upper surface of the bonding pad exposed from the opening is divided into a first region and a second region,
the shielding film is disposed on the first region, and
the electroless plating film is disposed on the shielding film in the first region and on the upper surface of the bonding pad in the second region.

2. The semiconductor device according to claim 1, wherein
the passivation film has a first passivation film and a second passivation film disposed on the first passivation film, and
the shielding film is formed from same material as a material of the second passivation film.

3. The semiconductor device according to claim 1, wherein
the passivation film has a first passivation film and a second passivation film disposed on the first passivation film, and
the shielding film includes a first layer formed from same material as a material of the cap film, a second layer formed on the first layer from same material as a material of the first passivation film and a third layer formed on the second layer from same material as a material of the second passivation film.

4. The semiconductor device according to claim 1, wherein
the shielding film includes a first layer formed from same material as a material of the cap film and a second layer formed on the first layer from same material as a material of the passivation film.

5. The semiconductor device according to claim 1, wherein the shielding film formed from same material as a material of the cap film.

6. The semiconductor device according to claim 1, wherein
the bonding pad is divided into a plurality of portions.

7. The semiconductor device according to claim 1, wherein
a relationship of Y<Z and X≤(Z−Y)×0.5 is satisfied where a width of the shielding film is X, a thickness of the shielding film is Y, and a thickness of the electroless plating film is Z.

8. The semiconductor device according to claim 1, wherein
a relationship of Y<Z and X>(Z−Y)×0.5 is satisfied where a width of the shielding film is X, a thickness of the shielding film is Y, and a thickness of the electroless plating film is Z.

9. The semiconductor device according to claim 1, wherein
the shielding film is divided into a plurality of portions,
the plurality of portions is disposed side by side at intervals along in a first direction in plan view, and
each of the plurality of portions is extended along in a second direction orthogonal to the first direction in plan view.

10. The semiconductor device according to claim 1, wherein
the second region is divided into a plurality of regions, and
each of the plurality of regions disposed side by side in a grid pattern at intervals in plan view.

11. The semiconductor device according to claim 1, further comprising:
a bonding wire connected to the electroless plating film, wherein
the shielding film has an annular portion which is an annular shape in plan view, and
the annular portion is disposed inside than a peripheral edge of the bonding wire connected to the electroless plating film in plan view, and a distance from the peripheral edge of the bonding wire is 0.2 times or less a width of the bonding pad in plan view.
